(19) United States
(12) Patent Application Publication
(10) Pub. No.: US 2007/0267720 A1
(43) Pub. Date: Nov. 22, 2007

(54) Semiconductor device including capacitor connected between two conductive strip groups

(75) Inventors: Takeshi Toda, Kanagawa (JP); Naoya Nakayama, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/798,862

(22) Filed: May 17, 2007

(30) Foreign Application Priority Data
May 18, 2006 (JP) 2006-138929

(51) Int. Cl. H01L 29/00

(52) U.S. Cl. 257/532; 257/535

(57) ABSTRACT

A semiconductor device includes an upper conductive strip group and a lower conductive strip group crossing under the upper conductive strip group. Adjacent first and second conductive strips of the upper conductive strip group are adapted to receive a first voltage, a third conductive strip of the lower conductive strip group is adapted to receive a second voltage. A capacitor is provided at a first intersection between the first and third conductive strips and at a second intersection between the second and third conductive strip, and the capacitor extends from the first intersection to the second intersection.

### BACKGROUND OF THE INVENTION

1. Field of the Invention

The present invention relates to a semiconductor device including so-called decoupling capacitors connected between power supply conductive strips and ground conductive strips for stabilizing a power supply voltage supplied to the power supply conductive strips and a ground voltage supplied to the ground conductive strips.

2. Description of the Related Art

In a semiconductor device, so-called decoupling capacitors are connected between power supply conductive strips and ground conductive strips, in order to stabilize a power supply voltage supplied to the power supply conductive strips and a ground voltage supplied to the ground conductive strips (see: WO00/67324 and U.S. Pat. No. 6,600,209B1). Also, a metal-insulator-metal (MIM) capacitor is disclosed in “A High Reliability Metal Insulator Metal Capacitor for 0.18 μm Copper Technology”, M. Armacost, A. Augustin, P. Felsner, Y. Feng, G. Friese, J. Heidenreich, G. Hueckel, O. Prigge, K. Stein (2000 IEEE).

A prior art semiconductor device is constructed by a plurality of lower conductive strips formed on a semiconductor substrate and extending in parallel to each other in a first direction and a plurality of upper conductive strips formed over the lower conductive strips and extending in parallel to each other in a second direction perpendicular to the first direction. The odd-numbered lower conductive strips receive a power supply voltage and the even-numbered lower conductive strips receive a ground voltage. Similarly, the odd-numbered upper conductive strips receive the power supply voltage and the even-numbered upper conductive strips receive the ground voltage. A plurality of unit capacitors are formed at intersections between the odd-numbered lower conductive strips and the even-numbered upper conductive strips and at intersections between the even-numbered lower conductive strips and the odd-numbered upper conductive strips (see; WO00/67324 and U.S. Pat. No. 6,300,209B1).

### SUMMARY OF THE INVENTION

In the above-described prior art semiconductor device, however, since each of the unit capacitors is provided only at the intersections between the lower conductive strips and the upper conductive strips, the capacitance of each of the unit capacitors is so small that the total capacitance of the unit capacitors is small. As a result, the unit capacitors would not sufficiently serve as a decoupling capacitor whose capacitance is required to be large.

According to the present invention, a semiconductor device includes an upper conductive strip group and a lower conductive strip group crossing under the upper conductive strip group. Adjacent first and second conductive strips of the upper conductive strip group are adapted to receive a first voltage, and a third conductive strip of the lower conductive strip group is adapted to receive a second voltage. A capacitor is provided at a first intersection between the first and third conductive strips and at a second intersection between the second and third conductive strip, and the capacitor extends from the first intersection to the second intersection.

Also, a semiconductor device includes an upper conductive strip group and a lower conductive strip group crossing under the upper conductive strip group. First and second conductive strips of the upper conductive strip group are adapted to receive a first voltage and a second voltage, respectively, and a third conductive strip of the lower conductive strip group is adapted to receive the second voltage. A capacitor includes a lower electrode layer, an upper electrode layer and a dielectric layer sandwiched by the lower electrode layer and the upper electrode layer. The upper electrode layer is connected to the conductive strip and the lower electrode layer is connected to the second conductive strip. The second conductive strip is connected to the third conductive strip.

On the other hand, a semiconductor device includes a lower conductive strip group and an upper conductive strip group crossing over the lower conductive strip group. Adjacent first and second conductive strips of the lower conductive strip group are adapted to receive a first voltage, and a third conductive strip of the upper conductive strip group is adapted to receive a second voltage. A capacitor is provided at a first intersection between the first and third conductive strips and at a second intersection between the second and third conductive strip, and the capacitor extends from the first intersection to the second intersection.

Also, a semiconductor device includes a lower conductive strip group and an upper conductive, strip group crossing over the upper conductive strip group. First and second conductive strips of the lower conductive strip group are adapted to receive a first voltage and a second voltage, respectively, and a third conductive strip of the upper conductive strip group is adapted to receive said second voltage. A capacitor includes a lower electrode layer, an upper electrode layer and a dielectric layer sandwiched by the lower electrode layer and the upper electrode layer. The lower electrode layer is connected to the conductive strip, the upper electrode layer is connected to the second conductive strip, and the second conductive strip is connected to the third conductive strip.

### BRIEF DESCRIPTION OF THE DRAWINGS

The present invention will be more clearly understood from the description set forth below, with reference to the accompanying drawings, wherein:

FIG. 1 is a plan view illustrating a first embodiment of the semiconductor device according to the present invention;

FIG. 2A is a first partial enlargement of the semiconductor device of FIG. 1;

FIG. 2B is a cross-sectional view taken along the line II-II of FIG. 2A;

FIG. 3A is a second partial enlargement of the semiconductor device of FIG. 1;

FIG. 3B is a cross-sectional view taken along the line III-III of FIG. 3A;

FIG. 4 is a plan view illustrating a second embodiment of the semiconductor device according to the present invention;

FIG. 5A is a first partial enlargement of the semiconductor device of FIG. 4;

FIG. 6B is a cross-sectional view taken along the line V-V of FIG. 5A;

FIG. 6A is a second partial enlargement of the semiconductor device of FIG. 4; and

FIG. 6B is a cross-sectional view taken along the line VI-VI of FIG. 6A.

### DESCRIPTION OF THE PREFERRED EMBODIMENTS

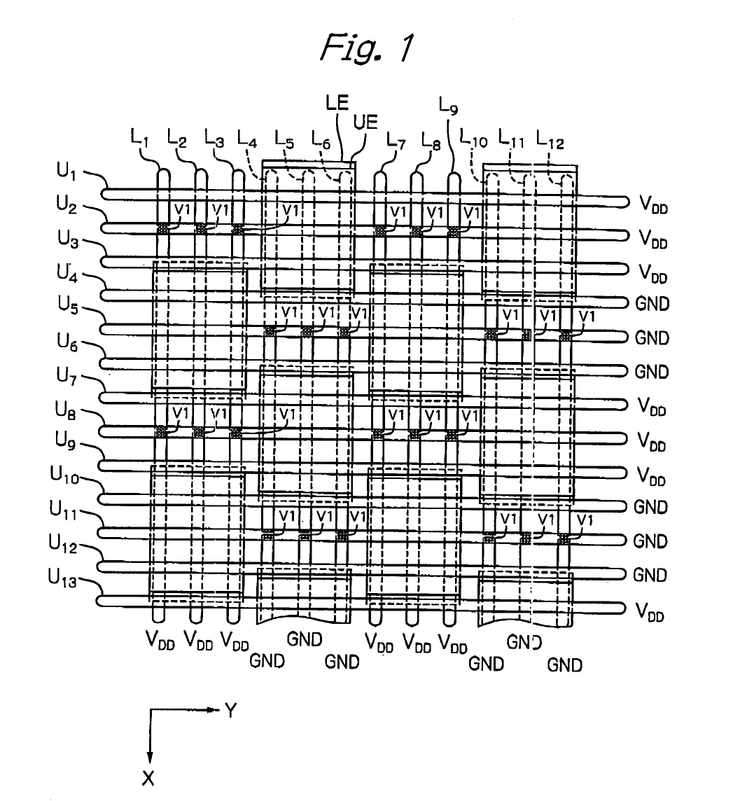

In FIG. 1, which illustrates a first embodiment of the semiconductor device according to the present invention, a plurality of lower conductive strips L₁, L₂, L₃, L₄, L₅, L₆, . . . extend in parallel to each other in an X direction, and upper conductive strips U₁, U₂, U₃, U₄, U₅, U₆, . . . extend in parallel to each other in a Y direction perpendicular to the X direction.

Every three lower conductive strips L₁, L₂, L₃, L₄, L₅, L₆; . . . alternately receive a power supply voltage V_{DD} and a ground voltage GND. That is, the lower conductive strips L₁, L₂, L₃; L₇, L₈, L₉; . . . receive the power supply voltage V_{DD}, and the lower conductive strips L₄, L₅, L₆; L₁₀, L₁₁, L₁₂ . . . receive the ground voltage GND. Similarly, every three upper conductive strips U₁, U₂, U₃; U₄, U₅, U₆; . . . alternately receive the power supply voltage V_{DD} and the ground voltage GND. That is, the upper conductive strips U₁, U₂, U₃; U₇, U₈, U₈; . . . receive the power supply voltage V_{DD}, and the upper conductive strips U₄, U₅, U₆; U₁₀, U₁₁, U₁₂ . . . receive the ground voltage GND.

Also, a plurality of capacitors each formed by one lower electrode layer LE and one upper electrode layer UE are staggered at every three lower conductive strips L₁, L₂, L₃, . . . , and at every three upper conductive strips U₁, U₂, U₃, . . . . In this case, all the capacitors have the same structure. Additionally, the spacing of the capacitors along the X direction is one upper conductive strip, while the spacing of the capacitors along the Y direction is minimum which would sufficiently prevent them from being short-circuited with each other. In more detail, one capacitor is provided between the three consecutive lower conductive strips receiving one of the power supply voltage V_{DD} and the ground voltage GND and the three consecutive upper conductive strips receiving the other of the power supply voltage V_{DD} and the ground voltage GND including their immediately adjacent upper conductive strips. Thus, the areas of the lower electrode layer LE and the upper electrode layer UE can be increased as compared with those of the three lower conductive strips and the three upper conductive strips. As a result, the capacitance of the capacitors can be increased, so that the voltages at the lower conductive strips and the upper conductive strips can be stabilized.

Particularly, since the lower electrode layer LE and the upper electrode layer UE extend a spacing between the lower conductive strips L₁, L₂, L₃, . . . and a spacing between the upper conductive strips U₁, U₂, U₃, . . . , the capacitance of the capacitors can be remarkably increased as compared with the prior art where capacitors are formed only at intersections between the lower conductive strips and the upper conductive strips.

Note that via structures V1 each formed by 3×3 vias are provided for connecting respective ones of the lower conductive strips to respective ones of the upper conductive strips, with the respective lower conductive strips and the respective upper conductive strips receiving the same voltage, thus further stabilizing the power supply voltage V_{DD} and the ground voltage GND.

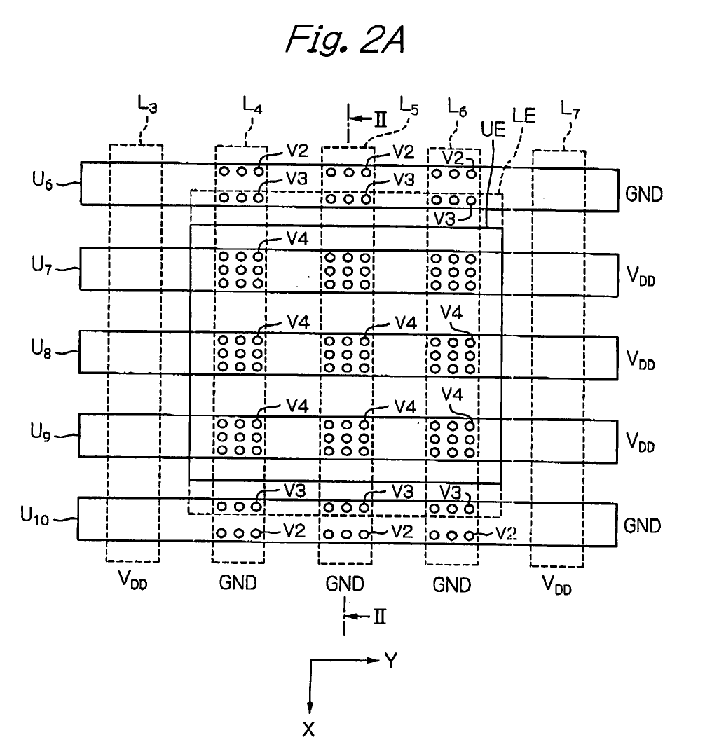

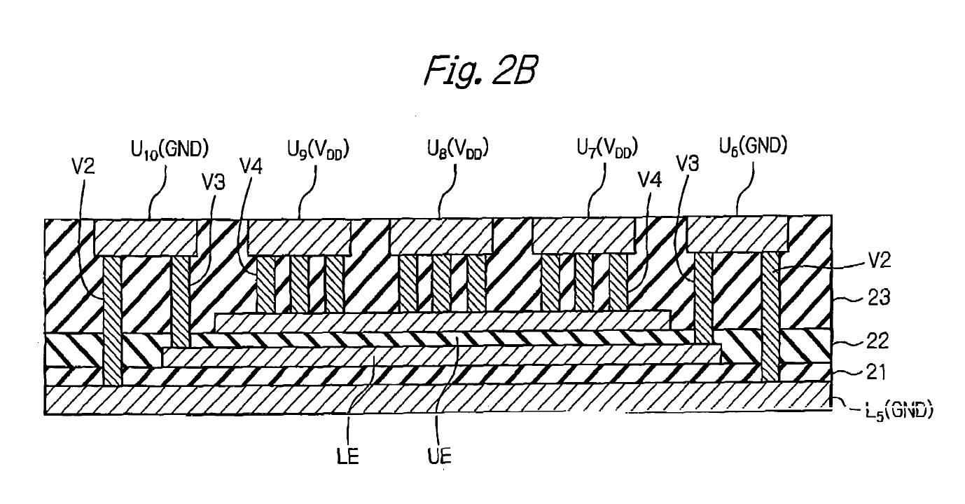

The capacitor of FIG. 1 which is formed between the lower conductive strips L₄, L₅ and L₆ and the upper conductive strips U₇, U₈ and U₉ including their immediately adjacent upper conductive strips U₆ and U₁₀ is explained next with reference to FIG. 2A and FIG. 2B which is a cross-sectional view taken along the line II-II of FIG. 2A.

As illustrated in FIG. 2A, the lower electrode layer LE opposes the three lower conductive strips L₄, L₅ and L₆ and the five upper conductive strips U₆, U₇, U₈, U₉ and U₁₀. On the other hand, the upper electrode layer UE opposes the three lower conductive strips L₄, L₅ and L₆ and the three upper conductive strips U₇, U₈ and U₉. That is, the lower electrode layer LE is outwardly protruded from the upper electrode layer UE along the X direction. This also would increase the capacitance of the capacitor.

The lower conductive strips L₄, L₅ and L₆ (=GND) are connected to the upper conductive strips U₆ and U₁₀ (=GND) with interstitial via structures V2 each formed by three vias.

The lower electrode layer LE (=GND) is connected to the upper conductive strips U₆ and U₁₀ (=GND) with interstitial via structures V3 each formed by three vias.

The upper electrode layer UE (=V_{DD}) is connected to the upper conductive strips U₇, U₈ and U₉ (−V_{DD}) with interstitial via structures V4 each formed by 3×3 vias.

Also, as illustrated in FIG. 2B, a semiconductor substrate (not shown) where semiconductor transistor circuits and the like are formed is provided. Also, an insulating layer (not shown) is formed on the semiconductor substrate. Then, the lower conductive layer such as L₅, an insulating interlayer 21, the lower electrode layer LE, a dielectric layer 22, the upper electrode layer UE and an insulating interlayer 23 are formed in this order.

Further, the via structures V2, V3 and V4 are formed within the insulating interlayer 21, the dielectric layer 22 and the insulating interlayer 23 simultaneous with the formation of the via structures V1 of FIG. 1. In this case, the via structures V2 are connected to the lower conductive strip L₅, the via structures V3 are connected to the lower electrode layer LE, and the via structures V4 are connected to the upper electrode layer UE.

Note that via structures (not shown) are formed, so that the lower conductive strips and the upper conductive strips are connected to the semiconductor substrate. As a result, the semiconductor substrate is subjected to the power supply voltage V_{DD} and the ground voltage GND. All the via structures V1, V2, V3 and V4 can be formed at once to decrease the manufacturing steps.

Additionally, the upper conductive strips U₆, U₇, U₈, U₉ and U₁₀ are formed on the insulating interlayer 23. In this case, the upper conductive strips U₆ and U₁₀ are connected by the via structures V2 and V3 to the lower conductive layer L₅ and the lower electrode layer LE. Also, the upper conductive strips U₇, U₈ and U₉ are connected by the via structure V4 to the upper electrode layer UE.

The insulating interlayer 23 is thicker than the insulating interlayer 21. For example, the insulating interlayers 21 and 23 are about 20 nm thick and about 500 nm thick, respectively. In this case, the thickness of the capacitor formed by the lower electrode layer LE, the upper electrode layer UE, the dielectric layer 22 sandwiched the lower electrode layer LE and the upper electrode layer UE is about 400 nm thick. As a result, the power supply voltage V_{DD} at the upper conductive strips U₇, U₈ and U₉ in stabilized directly by the capacitor, and the ground voltage GND is stabilized indirectly by the capacitor.

Additionally, the insulating interlayer 21 and 23 are so thick that a leakage current flowing from the upper conductive strips to the lower conductive strips can be suppressed.

Further, the lower electrode layer LE and the upper electrode layer UE of the capacitor are separated from the lower conductive strip L₅ and the upper conductive strips U₅, U₇, U₈, U₉ and U₁₀, so that the lower electrode layer LE can be in proximity to the upper electrode layer UE. As a result, the capacitance of the capacitor can be increased, which would further stabilize the power supply voltage V_{DD} and the ground voltage GND.

Additionally, since the upper conductive strips U₇, U₈ and U₉ receives the same voltage, i.e., the power supply voltage V_{DD}, so that there is no leakage current issue therebetween, the upper conductive strips U₇, U₈ and U₉ can be as close as possible. As a result, a chemical mechanical polishing (CMP) process can easily be performed upon the insulating interlayer 23.

Thus, in FIGS. 2A and 2B, the two adjacent upper conductive strips such as U₇ and U₈ receive the power supply voltage V_{DD}, and the lower conductive strip L₅ receives the ground voltage GND. The capacitor is provided at a first intersection between the upper conductive strip U₇ and the lower conductive strip L₆ and at a second intersection between the upper conductive strip U₈ and the lower conductive strip L₆. The capacitor extend from the first intersection to the second intersection.

Also, in FIGS. 2A and 2B, the upper electrode UE (=V_{DD}) is connected to the upper conductive strips U₇ and U₈ (=V_{DD}), while the lower electrode UE (=GND) is connected via the upper conductive strip U₆ (=GND) to the lower conductive strip L₅ (=GND).

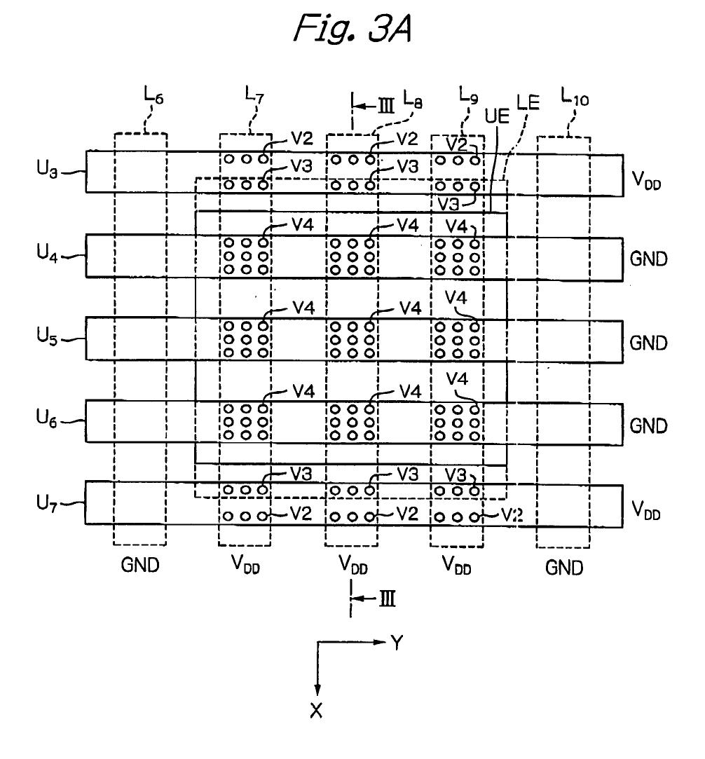

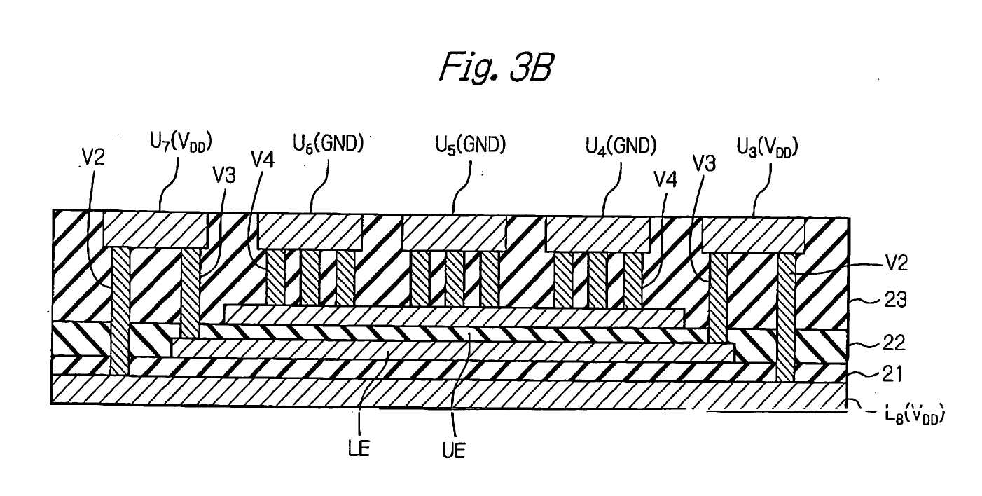

The capacitor of FIG. 1 which is formed between the lower conductive strips L₇, L₈ and L₉ and the upper conductive strips U₄, U₅ and U₆ including their immediately adjacent upper conductive strips U₃ and U₇ is explained next with reference to FIG. 3A and FIG. 3B which is a cross-sectional view taken along the line III-III of FIG. 3A.

As illustrated in FIG. 3A, the lower electrode layer LE opposes the three lower conductive strips L₇, L₈ and L₉ and the five upper conductive strips U₃, U₄, U₅, U₆ and U₇. On the other hand, the upper electrode layer UE opposes the three lower conductive strips L₇, L₈ and L₉ and the three upper conductive strips U₄, U₅ and U₆. That is, the lower electrode layer LE is also outwardly protruded from the upper electrode layer UE along the X direction. This also would increase the capacitance of the capacitor.

The lower conductive strips L₇, L₈ and L₉ (=V_{DD}) are connected to the upper conductive strips U₃ and U₇ (=V_{DD}) with interstitial via structures V2 each formed by three vias.

The lower electrode layer LE (=V_{DD}) is connected to the upper conductive strips U₃ and U₇ (=V_{DD}) with interstitial via structures V3 each formed by three vias.

The upper electrode layer UE (=GND) is connected to the upper conductive strips U₄, U₅ and U₆ (=GND) with interstitial via structures V4 each formed by 3×3 vias.

Also, as illustrated in FIG. 3B, in the same way as in FIG. 2B, the lower conductive layer such as L₈, an insulating interlayer 21, the lower electrode layer LE, a dielectric layer 22, the upper electrode layer UE and an insulating interlayer 23 are formed in this order. Further, the via structures V2, V3 and V4 are formed within the insulating interlayer 21, the dielectric layer 22 and the insulating interlayer 23 simultaneous with the formation of the via structures V1 of FIG. 1.

Thus, in FIGS. 3A and 3B, the two adjacent upper conductive strips such as U₄ and U₅ receive the ground voltage GND, and the lower conductive strip L₈ receives the power supply voltage V_{DD}. The capacitor is provided at a first intersection between the upper conductive strip U₄ and the lower conductive strip L₈ and at a second intersection between the upper conductive strip U₅ and the lower conductive strip L₈. The capacitor extends from the first intersection to the second intersection.

Also, in FIGS. 3A and 3B, the upper electrode UE (=GND) is connected to the upper conductive strips U₄ and U₆ ('GND), while the lower electrode UE (=V_{DD}) is connected via the upper conductive strip U₃ (=V_{DD}) to the lower conductive strip L₅ (=V_{DD}).

A method for manufacturing the semiconductor device of FIG. 1 is briefly explained below.

First, in accordance with a metal depositing process and a photolithography and etching process, lower conductive strips L₁, L₂, L₃, . . . are formed on an insulating layer which is formed on a semiconductor substrate where semiconductor transistor circuits are already formed.

Next, an about 20 nm thick insulating interlayer 21 is formed by a chemical vapor deposition (CVD) process. Then, a metal layer made of Ti, TiN, Ta or TaN is deposited and is patterned by a photolithography and etching process to complete the lower electrode layer LE.

Next, a dielectric layer 22 is formed by a CVD process. Then, a metal layer made of Ti, TiN, Ta or TaN is deposited and is patterned by a photolithography and etching process to complete the upper electrode layer UE.

Next, an about 500 nm thick insulating interlayer 23 is deposited by a CVD process. Then, a CMP process is performed upon the insulating interlayer 23 to flatten it.

Finally, via holes for via structures V1, V2, V3 and V4 and grooves for upper conductive strips U₁, U₂, . . . are formed by a dual damascene process. Then, metal is deposited and is buried in the via holes and grooves by a CMP process to complete the via structures V1, V2, V3 and V4 and the upper conductive strips U₁, U₂, . . . , which would avoid disconnection of the via structures V1, V2, V3 and V4 and the upper conductive strips U₁, U₂, . . . .

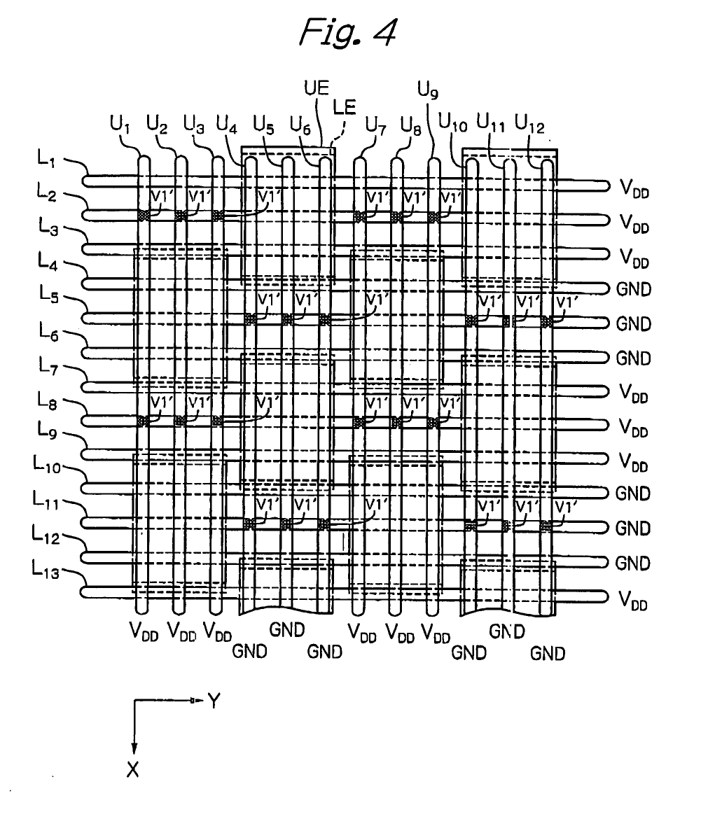

In FIG. 4, which illustrates a second embodiment of the semiconductor device according to the present invention, a plurality of upper conductive strips U₁, U₂, U₃, U₄, U₅, U₆, . . . extend in parallel to each other in the X direction, and lower conductive strips L₁, L₂, L₃, L₄, L₅, L₆, . . . extend in parallel to each other in the Y direction.

Even in this case, every three lower conductive strips L₁, L₂, L₃; L₄, L₅, L₆; . . . alternately receive the power supply voltage V_{DD} and the ground voltage GND, and every three upper conductive strips U₁, U₂, U₃; U₄, U₅, U₆; . . . alternately receive the power Supply voltage V_{DD} and the ground voltage GND.

Also, a plurality of capacitors each formed by one lower electrode layer LE and one upper electrode layer UE are staggered at every three lower conductive strips L₁, L₂, L₃, . . . , and at every three upper conductive strips U₁, U₂, U₃, . . . . In this case, all the capacitors have the same structure. Additionally, the spacing of the capacitors along the X direction is one lower conductive strip, while the spacing of the capacitors along the Y direction is minimum which would sufficiently prevent them from short-circuiting each other. In more detail, one capacitor is provided between the three consecutive upper conductive strips receiving one of the power supply voltage V_{DD} and the ground voltage GND and the three consecutive lower conductive strips receiving the other of the power supply voltage V_{DD} and the ground voltage GND including their immediately adjacent lower conductive strips. Thus, the areas of the lower electrode layer LE and the upper electrode layer UE can be increased as compared with those of the three lower conductive strips and the three upper conductive strips. As a result, the capacitance of the capacitors can be increased, so that the voltages at the lower conductive strips and the upper conductive strips can be stabilized.

Particularly, since the lower electrode layer LE and the upper electrode layer UE extend a spacing between the lower conductive strips L₁, L₂, L₃, . . . and a spacing between the upper conductive strips U₁, U₂, U₃, . . . , the capacitance of the capacitors can be remarkably increased as compared with the prior art where capacitors are formed only at intersections between the lower conductive strips and the upper conductive strips.

Note that via structures V1′ each formed by 3×3 vias are provided for connecting respective ones of the lower conductive strips to respective ones of the upper conductive strips, with the respective lower conductive strips and the respective upper conductive strips receiving the same voltage, thus further stabilizing the power supply voltage V_{DD} and the ground voltage GND.

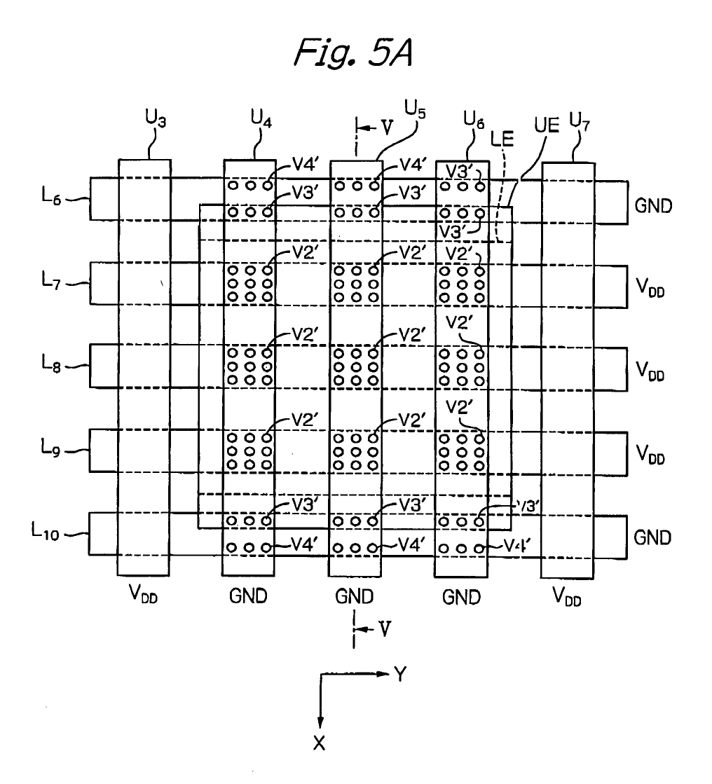

The capacitor of FIG. 4 which is formed between the upper conductive strips U₄, U₅ and U₆ and the lower conductive strips L₇, L₈ and L₉ including their immediately adjacent lower conductive strips L₆ and L₁₀ is explained next with reference to FIG. 5A and FIG. 5B which is a cross-sectional view taken along the line V-V of FIG. 5A.

As illustrated in FIG. 5A, the upper electrode layer UE opposes the three upper conductive strips U₄, U₅ and U₆ and the five lower conductive strips L₆, L₇, L₈, L₉ and L₁₀. On the other hand, the lower electrode layer LE opposes the three upper conductive strips U₄, U₅ and U₆ and the three lower conductive strips L₇, L₈ and L₉. That is, the upper electrode layer UE is outwardly protruded from the lower electrode layer LE along the X direction. This also would increase the capacitance of the capacitor.

The lower electrode layer LE (=V_{DD}) is connected to the lower conductive strips L₇, L₈ and L₉ (=V_{DD}) with interstitial via structures V2′ each formed by 3×3 vias.

The upper electrode layer UE (=GND) is connected to the lower conductive strips L₆ and L₁₀ (=GND) with interstitial via structures V3′ each formed by three vias.

The upper conductive strips U₄, U₅ and U₆ (=GND) are connected to the lower conductive strips L₆ and L₁₀ (=GND) with interstitial via structures V4′ each formed by three vias.

Also, as illustrated in FIG. 5B, a semiconductor substrate (not shown) where semiconductor transistor circuits and the like are formed is provided. Also, an insulating layer (not shown) is formed on the semiconductor substrate. Then, the lower conductive layers L₆, L₇, L₈, L₉ and L₁₀, an insulating interlayer 31, the lower electrode layer LE, a dielectric layer 32, the upper electrode layer UE, an insulating interlayer 33 and the upper conductive strip such as U₆ are formed in this order.

Further, the via structures V2′, V3′ and V4′ are formed within the insulating interlayer 31, the dielectric layer 32 and the insulating interlayer 33 with the formation of the via structures V1′ of FIG. 4. In this case, the via structures V2′ are connected between the lower electrode layer LE and the lower conductive strips L₇, L₈ and L₉, the via structures V3′ are connected between the upper electrode layer UE and the lower conductive strips L₆ and L₁₀, and the via structures V4′ are connected between the upper electrode layer UE and the lower conductive strips L₆ and L₁₀.

Note that via structures (not shown) are formed, so that the lower conductive strips and the upper conductive strips are connected to the semiconductor substrate. As a result, the semiconductor substrate is subjected to the power supply voltage V_{DD} and the ground voltage GND. Also, the via structures V1′, V2′, V3′ and V4′ are separately formed which would Increase the manufacturing steps.

The insulating interlayer 31 is thicker than the insulating interlayer 33. For example, the insulating interlayer 31 and 33 are about 500 nm thick and about 20 nm thick, respectively. In this case, the thickness of the capacitor formed by the lower electrode layer LE, the upper electrode layer UE, the dielectric layer 32 sandwiched by the lower electrode layer LE and the upper electrode layer UE is about 400 nm thick. As a result, the power supply voltage V_{DD} at the lower conductive strips L₇, L₈ and L₉ is stabilized directly by the capacitor, and the ground voltage GND is stabilized indirectly by the capacitor.

Additionally, the insulating interlayer 31 and 33 are so thick that a leakage current flowing from the lower conductive strips to the upper conductive strips can be suppressed.

Further, the lower electrode layer LE and the upper electrode layer UE of the capacitor are separated from the upper conductive strip U₅ and the lower conductive strips L₆, L₇, L₈, L₉ and L₁₀, so that the lower electrode layer LE can be in proximity to the upper electrode layer UE. As a result, the capacitance of the capacitor can be increased, which would further stabilize the power supply voltage V_{DD} find the ground voltage GND.

Additionally, since the upper conductive strips U₄, U₅ and U₆ receives the same voltage, i.e., the ground voltage GND, so that there is no leakage current issue therebetween, the upper conductive strips U₄, U₅ and U₆ can be as close as possible. As a result, a chemical mechanical polishing (CMP) process can easily be performed upon the insulating interlayer 33.

Thus, in FIGS. 5A and 5B, the two adjacent lower conductive strips such as L₇ and L₈ receive the power supply voltage V_{DD}, and the upper conductive strip U₅ receives the ground voltage GND. The capacitor is provided at a first intersection between the lower conductive strip L₇ and the upper conductive strip U₅ and at a second intersection between the lower conductive strip L₅ and the upper conductive strip U₅. The capacitor extends from the first intersection to the second intersection.

Also, in FIGS. 5A and 5B, the lower electrode LE (=V_{DD}) is connected to the lower conductive strips L₇ and L₈ (=V_{DD}), while the upper electrode UE (=GND) is connected via the lower conductive strip L₆ (=GND) to the upper conductive strip U₅ (=GND).

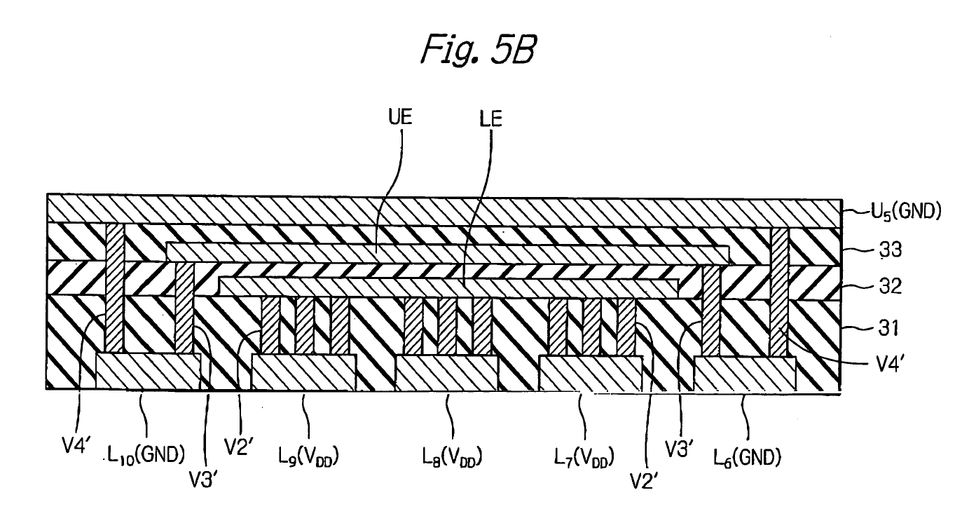

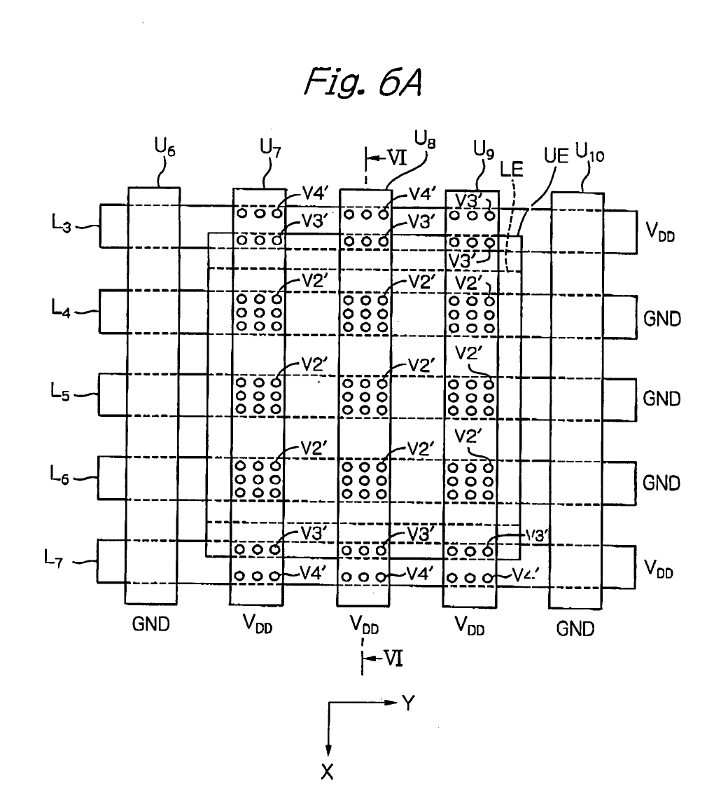

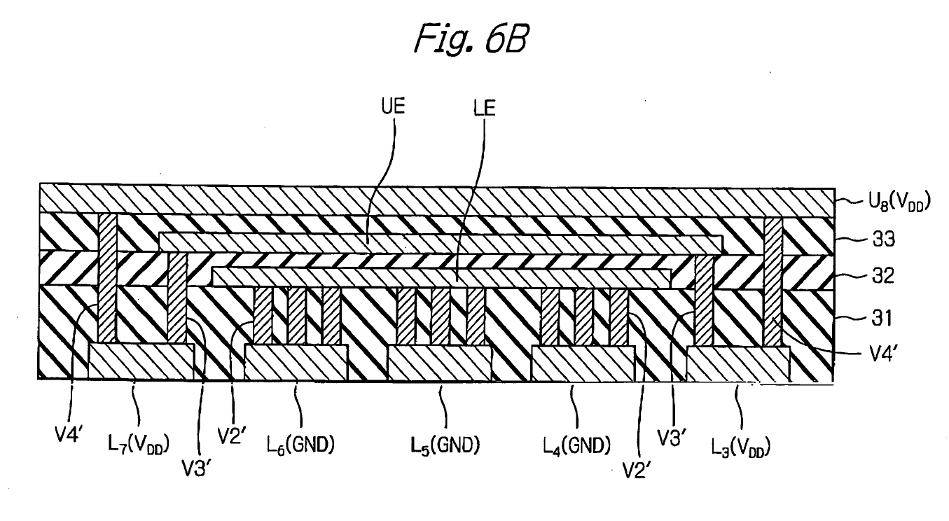

The capacitor of FIG. 4 which is formed between the upper conductive strips U₇, U₈ and U₉ and the lower conductive strips L₄, L₅ and L₆ including their immediately adjacent lower conductive strips L₃ and L₇ is explained next with reference to FIG. 6A and FIG. 6B which is a cross-sectional view taken along the line VI-VI of FIG. 6A.

As illustrated in FIG. 6A, the upper electrode layer UE opposes the three upper conductive strips U₇, U₈ and U₉ and the five lower conductive strips L₃, L₄, L₅, L₆ and L₇. On the other hand, the lower electrode layer LE opposes the three upper conductive strips U₇, U₈, and U₉ and the three lower conductive strips L₄, L₅ and L₆. That is, the upper electrode layer UE is also outwardly protruded from the lower electrode layer LE along the X direction. This also would increase the capacitance of the capacitor.

The lower electrode layer LE (=GND) is connected to the lower conductive strips L₄, L₅ and L₆ (=GND) with interstitial via structures V2′ each formed by 3×3 vias.

The upper electrode layer UE (=V_{DD}) is connected to the lower conductive strips L₃ and L₇ (=V_{DD}) with interstitial via structures V3′ each formed by three vias.

The upper conductive strips U₇, U₈ and U₉ (=V_{DD}) are connected to the lower conductive strips L₃ and L₇ (=V_{DD}) with interstitial via structures V4′ each formed by three vias.

Also, as illustrated in FIG. 6B, in the same way as in FIG. 5B, the lower conductive layers L₆, L₇, L₈, L₉ and L₁₀, an insulating interlayer 31, the lower electrode layer LE, a dielectric layer 32, the upper electrode layer UE, an insulating interlayer 33 and the upper conductive strip such as U₅ are formed in this order. Further, the via structures V2′, V3′ and V4′ are formed within the insulating interlayer 31, the dielectric layer 32 and the insulating interlayer 33 with the formation of the via structures V1′ of FIG. 4.

Thus, in FIGS. 6A and 6B, the two adjacent lower conductive strips such as L₄ and L₅ receive the ground voltage GND, and the upper conductive strip U₈ receives the power supply voltage V_{DD}. The capacitor is provided at a first intersection between the lower conductive strip L₄ and the upper conductive strip U₈ and at a second intersection between the lower conductive strip L₅ and the upper conductive strip U₈. The capacitor extends from the first intersection to the second intersection.

Also, in FIGS. 6A and 6B, the lower electrode LE (=GND) is connected to the lower conductive strips L₄ and L₅ (=GND), while the upper electrode UE (=V_{DD}) is connected via the lower conductive strip L₃ (=V_{DD}) to the upper conductive strip U₈ (=V_{DD}).

A method for manufacturing the semiconductor device of FIG. 4 is briefly explained below.

First, in accordance with a metal depositing process and a photolithography and etching process, lower conductive strips L₁, L₂, L₃, . . . are formed on an insulating layer which is formed on a semiconductor substrate where semiconductor transistor circuits are already formed.

Next, an about 500 nm thick insulating interlayer 31 is formed by a chemical vapor deposition (CVD) process. Then, via holes for via structures V2′ are formed, and metal is buried in the via holes by a CMP process to complete the via structures V2′. Then, a metal layer made of Ti, TiN, Ta or TaN is deposited and is patterned by a photolithography and etching process, so that the lower electrode layer LE is connected to the via structures V2′.

Next, a dielectric layer 32 is formed by a CVD process. Then, via holes for via structures V3′ are formed, and metal is buried in the via holes by a CMP process to complete the via structures V3′. Then, a metal layer made of Ti, TiN, Ta or TaN is deposited and is patterned by a photolithography and etching process, so that the upper electrode layer UE is connected to the via structures V3′.

Next, an about 20 nm thick insulating interlayer 33 is deposited by a CVD process. Then, via holes for via structures V4′ are formed, and metal is buried in the via boles by a CMP process to complete the via structures V4′.

Finally, grooves for upper conductive strips U₁, U₂, . . . are formed by a dual damascene process. Then, metal is deposited and is buried in the grooves by a CMP process to complete the upper conductive strips U₁, U₂, . . . , which would avoid disconnection of the upper conductive strips U₁, U₂, . . . .

In the above-described embodiments, every three lower conductive strips alternately receive the power supply voltage V_{DD} and the ground voltage GND; however, every two lower conductive strips or every four lower conductive strips or more can alternately receive the power supply voltage V_{DD} and the ground voltage GND. Similarly, every three upper conductive strips alternately receive the power supply voltage V_{DD} and the ground voltage GND; however, every two upper conductive strips or every four upper conductive strips or more can alternately receive the power supply voltage V_{DD} and the ground voltage GND.

1. A semiconductor device comprising:
an upper conductive strip group, adjacent first and second conductive strips of said upper conductive strip group being adapted to receive a first voltage;
a lower conductive strip group crossing under said upper conductive strip group, a third conductive strip of said lower conductive strip group being adapted to receive a second voltage; and
a capacitor provided at a first intersection between said first and third conductive strips end at a second intersection between said second and third conductive strip, said capacitor extending from said first intersection to said second intersection.

2. The semiconductor device as set forth in claim 1, wherein conductive strips of said upper conductive strip group including said first and second conductive strips extend in parallel to each other in a first direction, and conductive strips of said lower conductive strip group including said third conductive strip extend in parallel to each other in a second direction perpendicular to said first direction.

3. The semiconductor device as set forth in claim 1, wherein said capacitor comprises:
a lower electrode layer;
an upper electrode layer; and
a dielectric layer sandwiched by said lower electrode layer and said upper electrode layer,
said upper electrode layer being connected to said conductive strips,
said lower electrode layer being connected to a fourth conductive strip of said upper conductive strip group, said fourth conductive strip being adapted to receive said second voltage,
said fourth conductive strip being connected to said third conductive strip.

4. The semiconductor device as set forth in claim 3, further comprising:
a first via structure connected between said third and fourth conductive strips;
a second via structure connected between said lower electrode layer and said fourth conductive strip; and
third via structures connected between said upper electrode layer and said first and second conductive strips.

5. The semiconductor device as set forth in claim 3, wherein said lower electrode layer is outwardly protruded from said upper electrode layer.

6. The semiconductor device as set forth in claim 1, wherein said first voltage is one of a power supply voltage and a ground voltage, and said second voltage is the other of said power supply voltage and said ground voltage.

7. A semiconductor device comprising:
an upper conductive strip group, first and second conductive strips of said upper conductive strip group being adapted to receive a first voltage and a second voltage, respectively;
a lower conductive strip group crossing under said upper conductive strip group, a third conductive strip of said lower conductive strip group being adapted to receive said second voltage; and
a capacitor including a lower electrode layer, an upper electrode layer and a dielectric layer sandwiched by said lower electrode layer and said upper electrode layer,
said upper electrode layer being connected to said conductive strip,
said lower electrode layer being connected to said second conductive strip,
said second conductive strip being connected to said third conductive strip.

8. The semiconductor device as set forth in claim 7, wherein a fourth conductive strip of said upper conductive strip group adjacent to said first conductive strip is adapted to receive said first voltage,
said lower electrode layer and said upper electrode layer extending from an intersection between said first and third conductive strips to an intersection between said fourth and third conductive strips.

9. A semiconductor device comprising:
a lower conductive strip group, adjacent first and second conductive strips of said lower conductive strip group being adapted to receive a first voltage;
an upper conductive strip group crossing over said lower conductive strip group, a third conductive strip of said upper conductive strip group being adapted to receive a second voltage; and
a capacitor provided at a first intersection between said first and third conductive strips and at a second intersection between said second and third conductive strip, said capacitor extending from said first intersection to said second intersection.

10. The semiconductor device as set forth in claim 9, wherein conductive strips of said lower conductive strip group including said first and second conductive strips extend in parallel to each other in a first direction, and conductive strips of said upper conductive strip group including said third conductive strip extend In parallel to each other in a second direction perpendicular to said first direction.

11. The semiconductor device as set forth in claim 9, wherein said capacitor comprises:
a lower electrode layer;
an upper electrode layer; and
a dielectric layer sandwiched by said lower electrode layer and said upper electrode layer,
said lower electrode layer being connected to said conductive strips,
said upper electrode layer being connected to a fourth conductive strip of said lower conductive strip group, said fourth conductive strip being adapted to receive said second voltage,
said fourth conductive strip being connected to said third conductive strip.

12. The semiconductor device as set forth in claim 11, further comprising:
first via structures connected between said lower electrode layer and said first and second conductive strips;
a second via structure connected between said upper electrode layer and said fourth conductive strip; and
a third via structure connected between said third and fourth conductive strips.

13. The semiconductor device as set forth in claim 11, wherein said upper electrode layer is outwardly protruded from said lower electrode layer.

14. The semiconductor device as set forth in claim 9, wherein said first voltage is one of a power supply voltage and a ground voltage, and said second voltage is the other of said power supply voltage and said ground voltage.

15. A semiconductor device comprising:
a lower conductive strip group, first and second conductive strips of said lower conductive strip group being adapted to receive a first voltage and a second voltage, respectively;
an upper conductive strip group crossing over said upper conductive strip group, a third conductive strip of said upper conductive strip group being adapted to receive said second voltage; and
a capacitor including a lower electrode layer, an upper electrode layer and a dielectric layer sandwiched by said lower electrode layer and said upper electrode layer,
said lower electrode layer being connected to said conductive strip,
said upper electrode layer being connected to said second conductive strip,
said second conductive strip being connected to said third conductive strip.

16. The semiconductor device as set forth in claim 15, wherein a fourth conductive strip of said lower conductive strip group adjacent to said first conductive strip is adapted to receive said first voltage,
said lower electrode layer and said upper electrode layer extending from an intersection between said first and third conductive strips to an intersection between said fourth and third conductive strips.
